(19) United States
(12) Patent Application Publication
(10) Pub. No.: US 2025/0258973 A1
(43) Pub. Date: Aug. 14, 2025

(54) APPARATUSES, COMPUTER-IMPLEMENTED METHODS, AND COMPUTER PROGRAM PRODUCTS FOR GENERATING VEHICLE PARAMETER REPORTING CONFIGURATIONS

(71) Applicant: HONEYWELL INTERNATIONAL INC., CHARLOTTE, NC (US)

(72) Inventors: Sai Krishna Edara, Hyderabad (IN); Srikanth Kumar Nandi, Hyderabad (IN); Kandula Naresh Kumar Reddy, Hyderabad (IN); Ramchandra Reddy Kankanala, Hyderabad (IN)

(21) Appl. No.: 18/629,471

(22) Filed: Apr. 8, 2024

(30) Foreign Application Priority Data
Feb. 14, 2024 (IN) 202411010261

(51) Int. Cl. G06F 30/20

(52) U.S. Cl. CPC G06F 30/20

(57) ABSTRACT

A vehicle parameter reporting configuration generation system models historical data, calculates vehicle parameter variance and/or fault occurrence probability, and generates vehicle operation-related scenarios accordingly. Policy documents and region-based attributes may be incorporated into the vehicle operation-related scenarios. The vehicle operation-related scenarios are utilized to generate recommended vehicle parameter reporting configurations, including recommended vehicle parameters to be reported, and reporting criterion such as relating to timing, frequency, and/or retention. The recommended vehicle parameter reporting configurations may be reviewed and/or modified via a user interface and loaded onto an onboard system to direct the onboard system or subsystems thereof to report certain vehicle parameter and reporting criterion, such as during operation of a vehicle.

### CROSS REFERENCE TO RELATED APPLICATION

This application claims priority to Indian Application No. 202411010261, filed Feb. 14, 2024, and entitled, “APPARATUSES, COMPUTER-IMPLEMENTED METHODS, AND COMPUTER PROGRAM PRODUCTS FOR GENERATING VEHICLE PARAMETER REPORTING CONFIGURATIONS,” the entire contents of which is hereby incorporated by reference.

### TECHNICAL FIELD

Embodiments of the present disclosure are generally directed to vehicle parameter reporting configurations, and specifically to generating one or more recommended vehicle parameter reporting configurations by generating vehicle-operation-related scenarios.

### BACKGROUND

In several contexts, various systems report data and parameters from a vehicle to an external system(s) to enable or assist with troubleshooting, maintenance planning and prevention, communication management, and the like. One such context is in operation of an aircraft, in which vehicle parameter reporting configurations are loaded onto the aircraft to direct various systems to record certain parameters and indicate at what times and/or frequencies such recordings are made.

Applicant has discovered problems and/or other inefficiencies with configuring vehicle parameter reporting. Through applied effort, ingenuity, and innovation, Applicant has solved many of these identified problems by developing solutions embodied in the present disclosure, which are described in detail below.

### BRIEF SUMMARY

A computer-implemented method is provided, the computer-implemented method including generating a plurality of vehicle operation-related scenarios utilizing a model of historical data by at least calculating at least one of vehicle parameter variance or fault occurrence probability based at least in part on the model, and receiving a set of subject vehicle parameter values. The computer-implemented method further includes, based at least in part on the set of subject vehicle parameter values, accessing the plurality of vehicle operation-related scenarios to generate one or more recommended vehicle parameter reporting configurations, wherein the one or more recommended vehicle parameter reporting configurations comprise at least one vehicle parameter and an associated reporting criterion.

According to certain embodiments, the computer-implemented method further includes processing policy documents and region-based attributes to generate the plurality of vehicle operation-related scenarios. According to certain embodiments, the computer-implemented method further includes updating the model and the plurality of vehicle operation-related scenarios based at least in part on additionally received data, and responsive to the updating of the model and the plurality of the vehicle operation-related scenarios, outputting a notification indicating a change to the one or more recommended vehicle parameter reporting configurations.

According to certain embodiments, the computer-implemented method further includes generating one or more insights associated with the one or more recommended vehicle parameter reporting configurations.

According to certain embodiments, the computer-implemented method further includes configuring at least one of an operational parameter variance threshold or a fault occurrence probability threshold. According to certain embodiments, the computer-implemented method further includes generating the model by combining different vehicle parameter values from the historical data to insert as sets of vehicle parameters values in the model, and applying one or more machine learning algorithms to insert predicted vehicle parameter values in the model.

According to certain embodiments, the computer-implemented method further includes providing the one or more recommended vehicle parameter reporting configurations via a vehicle parameter reporting configuration development system, receiving an indication of at least one of a selection, a modification, or a submission of the one or more recommended vehicle parameter reporting configurations, and transmitting the one or more recommended vehicle parameter reporting configurations to an onboard system, wherein the onboard system directs reporting of vehicle parameter values based on the one or more recommended vehicle parameter reporting configurations.

According to certain embodiments, the one or more vehicle parameter reporting configurations include airline modifiable information. According to certain embodiments, the associated reporting criterion comprises at least one of a frequency of reporting, a retention period, or a retention policy. According to certain embodiments, the historical data comprises one or more of reports, fault history, or vehicle messaging information.

An apparatus is also provided, the apparatus comprising at least one processor and at least one memory, the at least one memory having computer-coded instructions stored thereon that, when executed by the least one processor, cause the apparatus to generate a plurality of vehicle operation-related scenarios utilizing a model of historical data by at least calculating at least one of vehicle parameter variance or fault occurrence probability based at least in part on the model.

The computer-coded instructions may further cause the apparatus to receive a set of subject vehicle parameter values, and, based at least in part on the set of subject vehicle parameter values, access the plurality of vehicle operation-related scenarios to generate one or more recommended vehicle parameter reporting configurations, wherein the one or more recommended vehicle parameter reporting configurations comprise at least one vehicle parameter and an associated reporting criterion.

According to certain embodiments, the computer-coded instructions further cause the apparatus to process policy documents and region-based attributes to generate the plurality of vehicle operation-related scenarios.

According to certain embodiments, the computer-coded instructions further cause the apparatus to update the model and the plurality of vehicle operation-related scenarios based at least in part on additionally received data, and responsive to the updating of the model and the plurality of the vehicle operation-related scenarios, output a notification indicating a change to the one or more recommended vehicle parameter reporting configurations.

According to certain embodiments, the computer-coded instructions further cause the apparatus to generate one or more insights associated with the one or more recommended vehicle parameter reporting configurations. According to certain embodiments, the computer-coded instructions further cause the apparatus to configure at least one of an operational parameter variance threshold or a fault occurrence probability threshold. According to certain embodiments, the computer-coded instructions further cause the apparatus to generate the model by combining different vehicle parameter values from the historical data to insert as sets of vehicle parameters values in the model, and appl one or more machine learning algorithms to insert predicted vehicle parameter values in the model.

According to certain embodiments, the computer-coded instructions further cause the apparatus to provide an indication of the one or more recommended vehicle parameter reporting configurations via a vehicle parameter reporting configuration development system, receive an indication of at least one of a selection, a modification, or a submission of the one or more recommended vehicle parameter reporting configurations, and transmit the one or more recommended vehicle parameter reporting configurations to an onboard system, wherein the onboard system directs reporting of vehicle parameter values based on the one or more recommended vehicle parameter reporting configurations.

A system is provided, including a vehicle parameter reporting configuration generation system and a vehicle parameter reporting configuration development system. The vehicle parameter reporting configuration generation system is configured to generate a plurality of vehicle operation-related scenarios, generate one or more recommended vehicle parameter reporting configurations, wherein the one or more recommended vehicle parameter reporting configurations comprise at least one vehicle parameter and an associated reporting criterion. The vehicle parameter reporting configuration generation system is configured to provide an indication of the one or more recommended vehicle parameter reporting configurations to a vehicle parameter reporting configuration development system. The vehicle parameter reporting configuration development system, configured to facilitate review, modification and submission of the recommended vehicle parameter reporting configurations to an onboard system, wherein the onboard system directs reporting of vehicle parameter values based on the one or more recommended vehicle parameter reporting configurations.

An apparatus is provided, the apparatus including means for generating a plurality of vehicle operation-related scenarios utilizing a model of historical data by at least calculating at least one of vehicle parameter variance or fault occurrence probability based at least in part on the model, and receiving a set of subject vehicle parameter values. The apparatus further includes, based at least in part on the set of subject vehicle parameter values, means for accessing the plurality of vehicle operation-related scenarios to generate one or more recommended vehicle parameter reporting configurations, wherein the one or more recommended vehicle parameter reporting configurations comprise at least one vehicle parameter and an associated reporting criterion.

According to certain embodiments, the apparatus further includes means for processing policy documents and region-based attributes to generate the plurality of vehicle operation-related scenarios.

According to certain embodiments, the apparatus further includes means for updating the model and the plurality of vehicle operation-related scenarios based at least in part on additionally received data, and responsive to the updating of the model and the plurality of the vehicle operation-related scenarios, outputting a notification indicating a change to the one or more recommended vehicle parameter reporting configurations.

According to certain embodiments, the apparatus further includes means for generating one or more insights associated with the one or more recommended vehicle parameter reporting configurations. According to certain embodiments, the apparatus further includes means for configuring at least one of an operational parameter variance threshold or a fault occurrence probability threshold. According to certain embodiments, the apparatus further includes means for generating the model by combining different vehicle parameter values from the historical data to insert as sets of vehicle parameters values in the model, and applying one or more machine learning algorithms to insert predicted vehicle parameter values in the model.

According to certain embodiments, the apparatus further includes means for providing the one or more recommended vehicle parameter reporting configurations via a vehicle parameter reporting configuration development system, receiving an indication of at least one of a selection, a modification, or a submission of the one or more recommended vehicle parameter reporting configurations, and transmitting the one or more recommended vehicle parameter reporting configurations to an onboard system, wherein the onboard system directs reporting of vehicle parameter values based on the one or more recommended vehicle parameter reporting configurations.

Other technical features may be readily apparent to one skilled in the art from the following figures, descriptions, and claims.

### BRIEF DESCRIPTION OF THE SEVERAL VIEWS OF THE DRAWINGS

FIG. 1 illustrates a block diagram of a system.

FIG. 2 illustrates a block diagram of an apparatus in accordance with at least one example embodiment of the present disclosure.

FIG. 3 illustrates a block diagram of an example system in which embodiments of the present disclosure may operate, and illustrates at least one improvement upon the system of FIG. 1.

FIG. 4 illustrates examples processes and data transformations according to at least one example embodiment of the present disclosure.

FIG. 5 is an example user interface display according to at least one example embodiment of the present disclosure.

FIG. 6 illustrates an example data flow according to at least one example embodiment of the present disclosure.

FIGS. 7-10 illustrate example flowcharts including operations of example embodiments of the present disclosure.

### DETAILED DESCRIPTION

Various embodiments of the present disclosure are described more fully hereinafter with reference to the accompanying drawings, in which some, but not all embodiments of the present disclosure are shown. Indeed, the present disclosure may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Terms such as “computing,” “determining,” “generating,” and/or similar words are used herein interchangeably to refer to the creation, modification, or identification of data. Further, “based on,” “based at least in part on,” “based at least on,” “based upon,” and/or similar words are used herein interchangeably in an open-ended manner such that they do not indicate being based only on or based solely on the referenced element or elements unless so indicated. Like numbers refer to like elements throughout.

### OVERVIEW

In several contexts, various systems report data and parameters are logged from a vehicle to an external system(s) to enable or assist with troubleshooting, maintenance planning and prevention, communication management, and the like. One such context is in operation of a commercial aerial vehicle, in which vehicle parameter reporting configurations are loaded onto the vehicle to direct various systems to record certain parameters, and indicate at what times and/or frequencies such recordings are made.

In the airline industry, some airplanes may include an onboard system, such as On-board Programmable Software (OPS), such as but not limited to:
Airplane Condition Monitoring Function (ACMF) that records, processes, and stores airplane systems data for report generation.
Flight Management Function (FMF) that helps to plan flights, predict fuel consumption, determine air mile distances, set altitudes, project estimated time of arrival, and to do other navigation functions.
Central Maintenance Computing Function (CMCF) that collects, stores, and shows maintenance data.
Communication Management Function (CMF) that provides an air-to-ground, two-way communication from airplane to ground.

It will be appreciated that the above systems are provided as examples of onboard systems that operate onboard an aircraft, and their functionalities, and that other systems, data, and functionalities may be implemented and/or modified according to certain example embodiments, including in other vehicle types.

A Ground Based Software Tool (GBST) is used by the Airlines/Original Equipment Manufacturers (OEMs) to customize the OPS for performing their operations and reporting through Airline Modifiable Information (AMI), the data file loaded onto the onboard system to direct certain functionalities including data reporting. In this regard, the AMI directs the onboard system and/or subsystems thereof to report certain vehicle parameters at specified time instants. The GBST and/or systems can then be used by engineers, other related subsystems and/or the like, to access and analyze the reported data for troubleshooting, maintenance, improving operations, and/or the like. According to certain embodiments, the data directed to be reported is accessed by engineers and/or other users via ground based applications after a flight. However, according to certain embodiments, some data, such as critical data can be downlinked while a vehicle is flying. In any event, customization of the AMI helps support airline-specific maintenance policies, and allows airlines to adhere to region based regulatory requirements. As another example, customization of AMI allows defining of a parametric report that is automatically downlinked when a specific fault is active. Additionally, customization of AMI allows for configuration of region-based frequencies for communication and subnetwork priority, and configuration of various checklists that need to be performed by the pilot, among other benefits.

An airline application modelling engineer models AMI in such a way that operations-related data is recorded which further will be used by technicians and engineers to analyze and make decisions to perform troubleshooting, maintenance and/or optimize the aircraft operations. The engineer customizes the AMI by interacting with the GBST, which outputs the AMI and is loaded onto the onboard system of the aircraft. However, utilizing the GBST to customize AMI and to therefore customize what data is reported from various aircraft systems requires extensive knowledge of AMI modeling engineers, and even the most experienced engineers fail to optimize AMI in a way that results in the desired data being recorded and made available for subsequent troubleshooting, maintenance, and the like, while avoiding, limiting or reducing excess or unnecessary reporting that otherwise consumes computer processing and memory resources, and associated power. The amount of data available to be captured in-flight from the various subsystems, as well as limited resources of onboard systems, such as but not limited to memory resources and processing resources, make it impractical and/or impossible to store every vehicle parameter at every time instant available. Network constraints and/or other communication resource constraints may additionally make it infeasible to report every vehicle parameter at every time instant data could be reported. Modeling the AMI in a way that directs more efficient and targeted data reporting way can improve the communication to ground systems, availability of data needed for troubleshooting, maintenance, and/or the like, and can therefore improve the overall functioning of the aircraft and related systems. In this regard, targeted data reporting refers to reporting data that is predicted as or identified as being useful to engineers, other users, and/or related systems in certain scenarios, and is captured and/or reported based on criterion (e.g., time frequency, and/or stored based on a certain retention period and/policy) that is also useful and adequate for enabling the engineers, other users, and/or related systems to perform the desired functions and/or analysis.

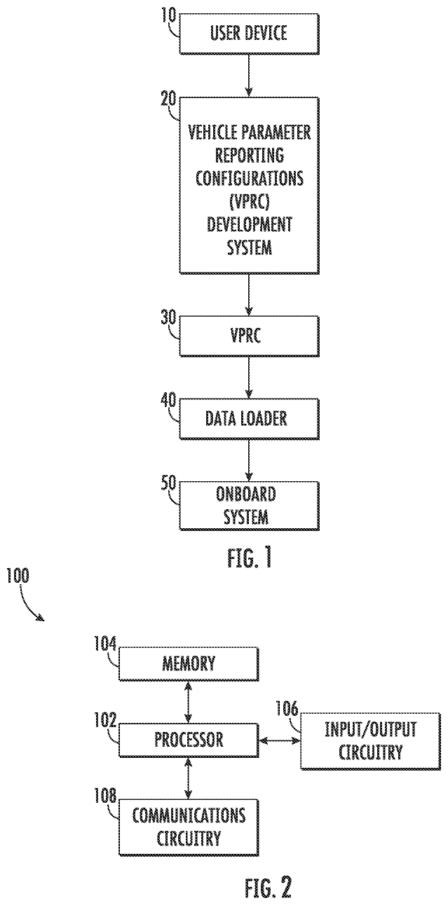

FIG. 1 illustrates an example system diagram which may be utilized according to existing systems. An AMI engineer or other user interacts with a user device 10 interfacing with a vehicle parameter reporting configurations (VPRC) development system. The VPRC development system may include a GBST, for example, that enables configuration of AMI. The vehicle parameter reporting configurations (VPRC) 30, or AMI, may be stored to a memory device, such as an AMI disk, then loaded by a processor of a data loader 40 onto an onboard system 50, which may include or be comprised by a core cabinet system of an aircraft. The VPRC loaded onto the onboard system 50 indicates to the various systems of the aircraft when and which parameters to report. The onboard system 50 directs reporting of vehicle parameter values based on the VPRCs.

In existing systems, the AMI generation process is a time-consuming process, and the airline application modelling engineers are dependent on various inputs to author and configure the AMI data. In existing systems, there is little or no intelligent guidance and recommendation process available for the AMI modelling engineer to guide them in configuring the aircraft operations data effectively.

Airlines face many challenges due to the current ineffective utilization of AMI capabilities. Some engineers' knowledge may be lacking in certain areas, or they may not be able to keep up to date with changing policies, changing operational environments, varying regional aspects and/or the like. The numerous parts and variables in maintenance and repairs can make it difficult or impossible for an engineer to learn every change or environmental factor that can impact certain scenarios on a particular aircraft or during an in-flight scenario. The high volume of flights per day—approximately 100,000 daily worldwide, in addition to numerous factors applicable to each flight and their respective outcomes with regard to troubleshooting, maintenance, and the like—makes it impractical or nearly impossible for an engineer to accurately, effectively, and efficiently identify what data reporting is needed. AMI modeling engineers may or may not immediately identify changes in regulation & airline policies regarding changes in data required to be reported, and/or related timing, frequency, and/or the like. Existing systems do not integrate with such regulatory and/or policy systems to automatically implement such changes. Additionally, when airplanes fly in different regions, the AMI should be configured based on various regional aspects (environmental conditions, alternate aerodromes/routes, and/or the like), but this may rely on an engineer's personal knowledge and/or research because such systems are also not integrated with the AMI in current systems. The above-described needs add further complexity to challenges associated with AMI configuration.

Consequences of sub-optimal AMI modeling can cause multiple downstream deficiencies and/or inefficiencies for airlines. If certain parametric data is missing or unavailable due to AMI modeling or configuration, aircraft maintenance engineers may experience difficulty in troubleshooting failures. Without certain data, airlines may be unable to optimize certain performance metrics, such as range and fuel efficiency. Attempts to improve fuel and range efficiency may be lacking critical factors that are overlooked based on the AMI modeled by engineers.

Embodiments of the present disclosure improve upon existing systems, such as the VPRC development system, or GBST, by intelligently generating and/or implementing recommended vehicle parameter reporting configurations, as described in further detail herein. In doing so, example embodiments further improve the efficiency of OPS and/or other onboard systems, and the overall efficiency and power efficiency of the vehicle, by limiting reporting and the frequency thereof to what is predicted as needed or beneficial, and on what time intervals, according to example embodiments disclosed herein.

In this regard, embodiments of the present disclosure generate a plurality of vehicle operation-related scenarios by generating a model of historical data and calculating operational parameter variance and/or fault occurrence probability. The model can therefore account for massive amounts of data recorded in varying scenarios as it is reported to example embodiments and/or ground based systems. Example embodiments can further apply subject vehicle parameters to the generated vehicle operations-related scenarios to make recommendations for vehicle parameter reporting configurations, including a parameter type and associated reporting criterion (e.g., frequency of reporting, a retention period, or a retention policy). Utilizing a model that can be routinely updated and monitored, according to example embodiments, provides near-instant information and knowledge to be gleaned from historical data and reflected in AMI to be loaded onto aircraft to impact subsequent reporting needs.

### Definitions

“Vehicle” refers to any machine, robot, apparatus, or other construction that traverses via at least one medium. Non-limiting examples of a vehicle include, without limitation, an aerial vehicle, a drone, a commercial airliner, a car, a truck, an autonomous vehicle, a boat, a submarine, and a multi-medium traversing machine.

“Onboard system” refers to hardware, software, firmware, and/or any combination thereof, that is onboard a vehicle and stores, processes, and/or otherwise utilizes various data according to example embodiments. The onboard system may perform various functionalities associated with operation of the vehicle. The onboard system may include, by way of non-limiting example, an OPS, an ACMF, an FMF, a CMCF, a CMF, and/or the like.

“Vehicle parameter” includes any data, property, field, and/or the like, that is reported from an onboard system, relating to the vehicle or operation of the vehicle. Non-limiting examples of a vehicle parameter include, for example, various measurements or readings from various components of the onboard system. “Value” may refer to contents of a parameter at a given time instant.

“Vehicle parameter reporting configuration” (VPRC) refers to computer-readable data that instructs the onboard system to record, obtain, or otherwise determine certain parameters, and optionally at specified frequencies and/or times and/or with a specified retention period and/or retention policy. As a non-limiting example, the VPRC includes AMI. The VPRC may include a binary file, for example, that is loaded onto an onboard system to direct certain functionalities including the reporting of data. The onboarding system or systems thereof may access the VPRC to determine what parameter types should be recorded, and reports generated, and when.

“Data loader” refers to a hardware, software, firmware, and/or any combination thereof, that facilitates transfer of the VPRC to an onboard system via a network.

“Vehicle parameter reporting configuration development system” (VPRC development system) refers to a hardware, software, firmware, and/or any combination thereof, that enables user interaction to select, create, modify, and/or submit VPRC and/or recommend VPRC. The VPRC development system, may include, as a non-limiting example, a GBST.

“Vehicle parameter reporting configuration generation system” (VPRC generation system) refers to a hardware, software, firmware, and/or any combination thereof, that generates vehicle operation-related scenarios and recommended vehicle parameter reporting configurations. Recommended VPRCs generated by the VPRC generation system may be provided to the VPRC development system.

“User device” refers to any hardware, software, firmware, and/or any combination thereof, connected to a computing device configured to enable user interaction and access to various components described herein, including but not limited to one utilized to access the VPRC development system.

“Model” refers to computer-readable data, including historical data. The historical data, may include values of any vehicle parameters previously recorded and/or downloaded from an onboard system, and may be associated with particular time instances. The historical data may further include outcomes associated with the vehicle parameter values, and may further include data representative of fault occurrence, fault history, one or more reports, vehicle messaging information, and/or the like.

“Vehicle parameter variance” refers to a calculated prediction of variance, based on the model, of a value of a vehicle parameter, given a certain combination or set of other values of vehicle parameters. Vehicle parameter variance may be calculated as a percentage, for example.

“Fault occurrence probability” refers to a calculated probability of a certain fault occurring given a certain combination of values of vehicle parameters. Fault occurrence probability may be calculated as a percentage, for example.

“Vehicle operation-related scenarios” refers to computer-readable data comprising a set of one or more vehicle parameters and respective values and/or value ranges, and associations with any number of corresponding recommended VPRCs that are recommended when subject vehicle parameters have one or more corresponding values that match or fall within one or more of the value ranges. The vehicle operation-related scenarios may be generated by the VPRC generation system based on vehicle parameter variance, fault occurrence probability, policy, region-based attributes and/or the like.

“Subject vehicle parameter values” refer to values of vehicle parameters for which recommended VPRC are generated or requested to be generated.

“Wireless communications network” refers to any one or more digital and/or physical connections that enable over-the-air communications between at least a first computing device embodied in hardware, software, firmware, and/or any combination thereof, and a second computing device embodied in hardware, software, firmware, and/or any combination thereof. Non-limiting examples of a wireless communications network include the Internet, Bluetooth, ZigBee, NFC, Wi-Fi, WAN, LAN, PAN, MAN, and a hybrid network including at least a portion of wired connections.

### EXAMPLE APPARATUSES AND SYSTEMS OF THE DISCLOSURE

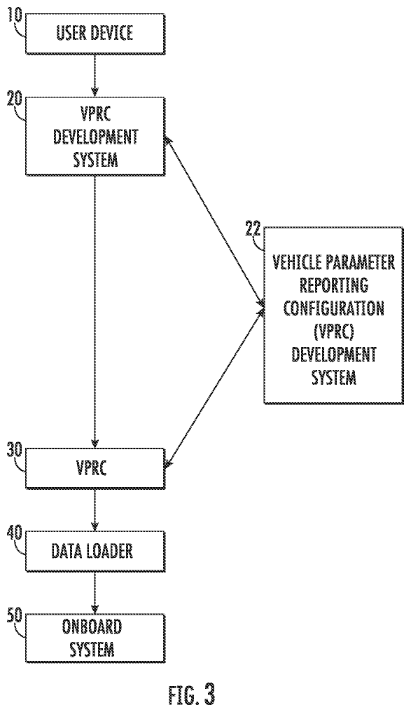

FIG. 2 illustrates a block diagram of an apparatus 100 embodying a VPRC generation system in accordance with at least one example embodiment of the present disclosure. Apparatus 100 may additionally or alternatively embody user device 10, VPRC development system 20, data loader 40, the onboard system 50, and/or the like.

The apparatus 100 includes processor 102, memory 104, input/output circuitry 106, and/or communications circuitry 108. In some embodiments, the apparatus 100 is configured, using one or more of the sets of circuitry embodied by processor 102, memory 104, input/output circuitry 106, communications circuitry 108, to execute and perform the operations described herein.

In general, the terms computing entity, device, system, and/or similar words used herein interchangeably may refer to, for example, one or more computers, computing entities, desktop computers, distributed systems, terminals, servers or server networks, gateways, switches, processing devices, processing entities, set-top boxes, relays, routers, network access points, base stations, the like, and/or any combination of devices or entities adapted to perform the functions, operations, and/or processes described herein. A user device may include any of the aforementioned computing devices and/or mobile phones, tablets, phablets, notebooks, laptops, and/or the like. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably. In this regard, the apparatus 100 embodies a particular, specially configured computing entity transformed to enable the specific operations described herein and provide the specific advantages associated therewith, as described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), network interface(s), storage medium(s), and/or the like, to perform their associated functions, such that duplicate hardware is not required for each set of circuitry. The use of the term “circuitry” as used herein with respect to components of the apparatuses described herein should therefore be understood to include particular hardware configured to perform the functions associated with the particular circuitry as described herein.

Particularly, the term “circuitry” should be understood broadly to include hardware and, in some embodiments, software for configuring the hardware. For example, in some embodiments, “circuitry” includes processing circuitry, storage media, network interfaces, input/output devices, and/or the like. Alternatively or additionally, in some embodiments, other elements of the apparatus 100 provide or supplement the functionality of another particular set of circuitry. For example, the processor 102 in some embodiments provides processing functionality to any of the sets of circuitry, the memory 104 provides storage functionality to any of the sets of circuitry, the communications circuitry 108 provides network interface functionality to any of the sets of circuitry, and/or the like.

In some embodiments, the processor 102 (and/or co-processor or any other processing circuitry assisting or otherwise associated with the processor) is/are in communication with the memory 104 via a bus for passing information among components of the apparatus 100. In some embodiments, for example, the memory 104 is non-transitory and may include, for example, one or more volatile and/or non-volatile memories. In other words, for example, the memory 104 in some embodiments includes or embodies an electronic storage device (e.g., a computer readable storage medium). In some embodiments, the memory 104 is configured to store information, data, content, applications, instructions, or the like, for enabling the apparatus 100 to carry out various functions in accordance with example embodiments of the present disclosure.

The processor 102 may be embodied in a number of different ways. For example, in some example embodiments, the processor 102 includes one or more processing devices configured to perform independently. Additionally or alternatively, in some embodiments, the processor 102 includes one or more processor(s) configured in tandem via a bus to enable independent execution of instructions, pipelining, and/or multithreading. The use of the terms “processor” and “processing circuitry” should be understood to include a single core processor, a multi-core processor, multiple processors internal to the apparatus 100, and/or one or more remote or “cloud” processor(s) external to the apparatus 100.

In an example embodiment, the processor 102 is configured to execute instructions stored in the memory 104 or otherwise accessible to the processor. Alternatively or additionally, the processor 102 in some embodiments is configured to execute hard-coded functionality. As such, whether configured by hardware or software methods, or by a combination thereof, the processor 102 represents an entity (e.g., physically embodied in circuitry) capable of performing operations according to an embodiment of the present disclosure while configured accordingly. Alternatively or additionally, as another example in some example embodiments, when the processor 102 is embodied as an executor of software instructions, the instructions specifically configure the processor 102 to perform the algorithms embodied in the specific operations described herein when such instructions are executed.

As one particular example embodiment, the processor 102 is configured to perform various operations associated with generating recommended VPRCs. In some such embodiments, the processor 102 includes hardware, software, firmware, and/or a combination thereof that models historical data, calculates vehicle parameter variance and fault occurrence probability, and generates vehicle operation-related scenarios. The processor 102 may therefore include hardware, software, firmware, and/or a combination thereof that accesses the plurality of vehicle operation-related scenarios to generate the recommended VPRCs. As another example, when apparatus 100 is embodied by the onboard system, the processor 102 processes VPRCs loaded onto the onboard system, to direct the onboard system regarding reporting of certain vehicle parameters.

In some embodiments, the apparatus 100 includes communications circuitry 108. The communications circuitry 108 includes any means such as a device or circuitry embodied in either hardware or a combination of hardware and software that is configured to receive and/or transmit data from/to a network and/or any other device, circuitry, or module in communication with the apparatus 100. In this regard, in some embodiments the communications circuitry 108 includes, for example, a network interface for enabling communications with a wired or wireless communications network. Additionally or alternatively in some embodiments, the communications circuitry 108 includes one or more network interface card(s), antenna(s), bus(es), switch(es), router(s), modem(s), and supporting hardware, firmware, and/or software, or any other device suitable for enabling communications via one or more communications network(s). Additionally or alternatively, the communications circuitry 108 includes circuitry for interacting with the antenna(s) and/or other hardware or software to cause transmission of signals via the antenna(s) or to handle receipt of signals received via the antenna(s). In some embodiments, the communications circuitry 108 enables transmission to and/or receipt of data amongst various components described herein. For example, the communications circuitry 108 may facilitate communication of recommended VPRCs from the VPRC generation system to the VPRC development system 20 and/or user device 10. Once submitted, reviewed, and/or finalized by an engineer, the VPRC may be communicated from the VPRC development system 20 to the onboard system 50.

Additionally or alternatively, in some embodiments, two or more of the sets of circuitries embodying processor 102, memory 104, input/output circuitry 106, communications circuitry 108, are combined. Alternatively or additionally, in some embodiments, one or more of the processor 102, memory 104, input/output circuitry 106, communications circuitry 108, perform some or all of the functionality described associated with another component. For example, in some embodiments, two or more of the processor 102, memory 104, input/output circuitry 106, communications circuitry 108, are combined into a single module embodied in hardware, software, firmware, and/or a combination thereof.

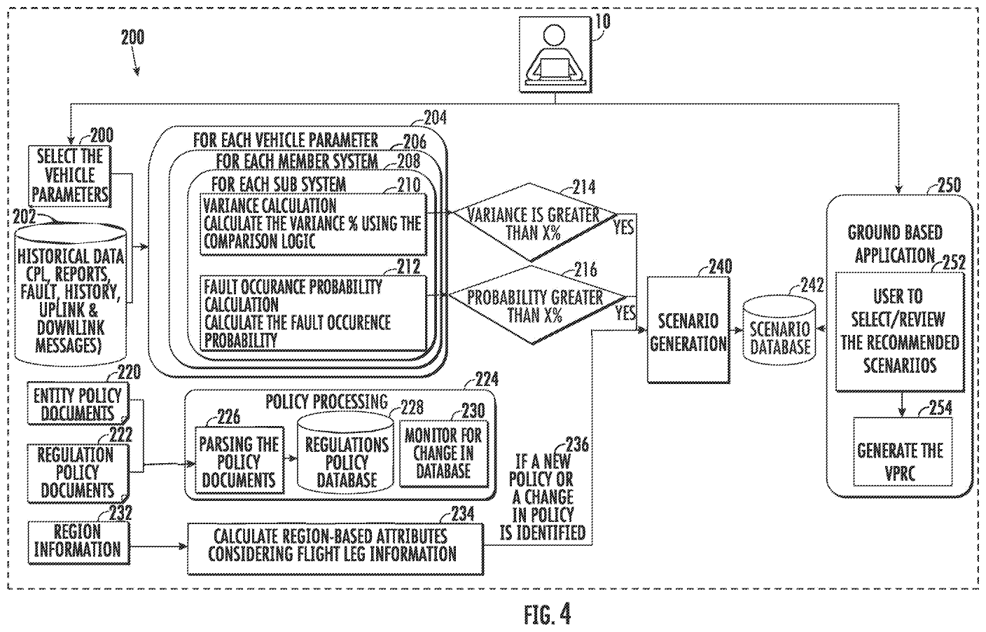

FIG. 3 illustrates an example system architecture according to example embodiments disclosed herein. FIG. 3 is similar to FIG. 1, but further introduces VPRC generation system 22. The VPRC generation system 22 may be embodied by apparatus 100, and is configured, such as with processor 102, to generate vehicle operation-related scenarios and recommended VPRCs, and provide the recommended VPRCs to the VPRC development system 20. Accordingly, a user interacting with the VPRC development system 20, such as with user device 10, reviews the recommended VPRCs, and may further modify VPRC 30 accordingly, and/or submit VPRC 30 for subsequent loading onto the onboard system 50 by the data loader 40. The VPRC 30 facilitates review, modification and submission of the recommended vehicle parameter reporting configurations to the onboard system 50. The onboard system 50 directs reporting of vehicle parameter values based on the recommended VPRCs In this regard, the VPRC development system 20 may be modified and improved to receive, populate, and/or default in its interface, recommended VPRCs provided by the VPRC generation system 22 according to example embodiments disclosed herein. The onboard system 50 may therefore be improved according to example embodiments, based on the population of recommended VPRCs that improve the effectivity of various onboard subsystems, and reporting processes therefrom.

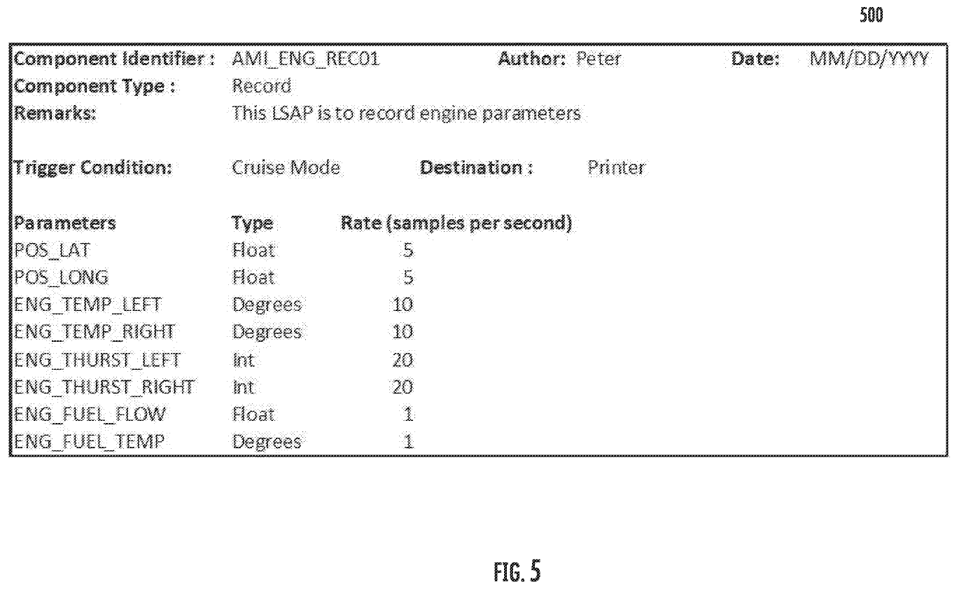

FIG. 4 illustrates examples processes and data transformations provided according to example embodiments disclosed herein. At operation 200, the user selects vehicle parameters, such as subject vehicle parameter values of a subject vehicle for which VPRC is desired or requested. According to certain embodiments selection of the vehicle parameters may be performed with or via user device 10 and/or a ground based application 250, such as the GBST and/or VPRC development system.

Optionally independently of operation 200, historical data 202, including but not limited to continuous parameter logging (CPL) data, reports, fault history, uplink and downlink messages, and/or the like, is processed by the VPRC generation system 22 to generate a model. The VPRC generation system 22, such as with processor 102, for each vehicle parameter 204, each member system 206, and for each subsystem 208, calculates vehicle parameter variance 210 and/or or fault occurrence probability 212. The model may therefore incorporate a vast amount of combinations of vehicle parameters values taken from historical data and calculate associated vehicle parameter variance and/or fault occurrence. According to certain embodiments, machine learning algorithms may be applied to the historical data to predict variance calculations and/or fault occurrence probability calculations for data sets that may not necessarily be represented in the historical data. In this regard, machine learning algorithms, including deep learning algorithms, may determine various weights of, or impacts by, certain vehicle parameters in producing particular outcomes, such as but not limited to fault occurrence. Additionally or alternatively, VPRC generation system 22 may determine how different vehicle parameter values result in different levels of variance of particular other vehicle parameter values. The model may perform various predictive and/or statistical calculations to determine certain ranges of vehicle parameters, respective values and/or ranges of corresponding vehicle parameters and/the like. The processor 104 may identify relationships between one or more vehicle parameters and/or the like. Numerous variations and implementations may be contemplated.

The model can then be utilized by the VPRC generation system 22 to perform scenario generation 240 when a predicted variance is greater than X % (214) and/or a probability of fault occurrence is greater than Y % (216). Resultant vehicle operation-related scenarios include one or more vehicle parameters and respective values and/or value ranges, along with corresponding recommended VPRCs that are recommended when subject vehicle parameters have corresponding values that match or fall within a range of a vehicle operation-related scenario, and are stored in scenario database 242.

According to certain embodiments, the probability of the fault occurrence may be calculated from the historical data for a particular vehicle model (e.g., aircraft model) for all sub-systems. When the fault occurrence probability factor exceeds a certain value, the correlated probability factor related scenarios are short listed (e.g., flagged with an indicator) and stored into the scenario database 242. According to certain embodiments, fault occurrence probability=Number of total number of faults occurred/total number of instances of data available. According to certain embodiments, fault occurrence probability may be an estimated or predicted calculation made using the model, which may include and incorporate various predictions and/or value ranges such that the probability of fault occurrence is predicted accordingly.

According to certain embodiments, the variance of the vehicle parameters from the historical data for a particular aircraft model is calculated for all sub-systems. When the variance exceeds a certain value, such as one configured by a user or entity (e.g., airline), the correlated vehicle parameters are collated, and respective scenarios are stored into the scenario database 242. The snapshot of the subsystem data across different tails for each of the flight attribute is compared to calculate the variance. For each vehicle parameter of a sub-system, the vehicle parameter value is compared against the mean of the parameters across all airplanes. The variation of the vehicle parameter with the mean is calculated. According to certain embodiments, sub-system variance factor=average of the variance for parameters for a subsystem. The vehicle parameters incorporated into a variance calculation may include all the parameters for a subsystem, or a subset of vehicle parameters for the subsystem.

According to certain embodiments, a troubleshooting algorithm may loop through various combinations of vehicle parameters, and recursively calculate a fault occurrent probability for one or more subsystems. Scenarios are generated at 240 based on the calculated probability and stored in the scenarios database 242. The troubleshooting approach takes calculated probability as input and generates trouble shooting scenarios based on probability factor limits. The generated troubleshooting scenarios are populated into scenario database 242.

According to certain embodiments, an improved airline operations algorithm may loop through certain vehicle parameters (which can be configured by the user, such as flight hours, flight leg, crew operations etc.), and recursively calculate the variance in the historical data. The calculated variance factor data is fed as an input to scenario generation 240 such that when certain indicated variance thresholds are met or exceeded, corresponding vehicle operation-related scenarios are generated in scenarios database 242.

According to certain embodiments, scenario generation 240 may be further impacted by entity policy documents 220 (e.g., airline police documents), and/or regulation policy documents 222. For example, the VPRC generation system 22 may perform policy processing 224 by parsing the policy documents (226), accessing a regulations and/or policy database 228, and/or monitoring for change (230) in the regulations and/or policy database 228. If a new policy or change in a policy is identified (236), the vehicle operation-related scenarios are updated accordingly. A regulation/airline policy-based algorithm may continuously monitor the policy database for any changes. Different entities, or airlines, may have their own entity policy documents 220 and/or regulation policy documents 222 such that respective scenarios vary across entities and/or airline accordingly. Scenarios will be generated using scenario generation 240, based on changes in the policies as input, and stored in scenarios database 242.

According to certain embodiments, scenario generation 240 may be further impacted by region information 232. For example, the VPRC generation system 22 may calculate region-based attributes considering location, or flight leg information, at 234. The region-based algorithm will calculate the region-based attributes based on location, or the flight leg information for the respective vehicle and/or airplane. Scenarios will be generated using scenario generation 240 and based on region-based attributes as input and stored in the scenarios database.

According to certain embodiments fault occurrence probability, variance factor, changes to the airline/regulations policy and the region attributes are given as in input to the scenario generation 240. According to certain embodiments, for each of the inputs, weightage factors may be calculated. In this regard, depending on subject vehicle parameters, related scenarios associated with the weightage factor can be accessed from the scenario database. Recommended scenarios can be accessed via the ground based application 250, such as GBST, and may be selected in response to user input relating to subject vehicle parameters. The VPRC 22 generates the VPRC accordingly, at 254. A user such as an application modelling engineer reviews the recommended scenarios, and selects and/or reviews the recommended scenarios at 252, and makes selections and/or modifications. Once selected or finalized, corresponding VPRC can be loaded onto an onboard system 50 to direct recording of vehicle parameters accordingly.

### EXAMPLE USER INTERFACE DISPLAY OF THE DISCLOSURE

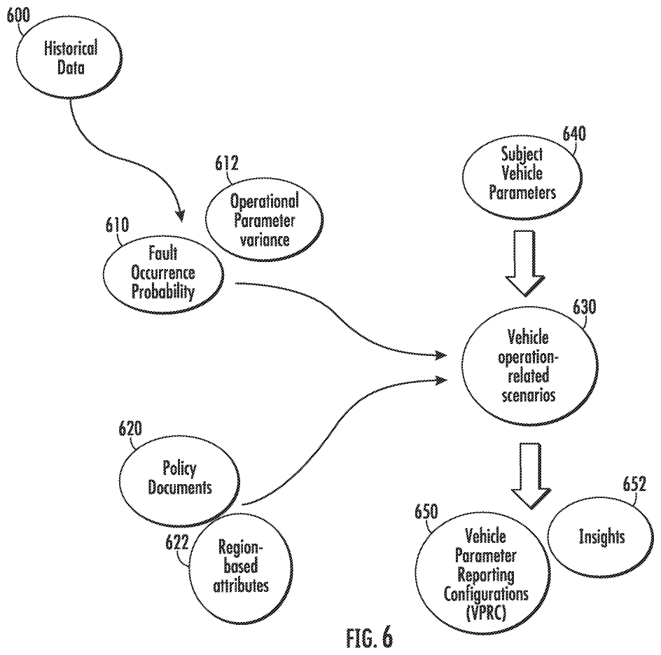

FIG. 5 is an example user interface display 500, that may be provided by the VPRC development system 20 and/or VPRC generation system 22, according to example embodiments, via user device 10. In this regard, any of the data displayed or recommended according to the user interface display may be populated with recommended VPRCs generated by the VPRC generation system 22. Upon selection of a report in the VPRC development system 20, a detailed view of its configuration is provided, such as provided in FIG. 5. Reporting criterion for the report may optionally be displayed (not shown in FIG. 5), including but not limited to a configurable number of reports per flight leg, a storage policy including selectable options to keep first or keep last, a configurable number of legs to keep a report, a configurable maximum number of reports, a selectable option to indicate automatic downlink on deactivation, and/or the like. It will be appreciated that other reporting criterion, such as related to frequency, retention period, retention policy, and/or the like, may be contemplated (not shown in FIG. 5). The retention period and/or policy may relate to how long the associated reports and/or parameters are stored on memory 104. FIG. 5 includes groups of vehicle parameters, with corresponding types and rates (e.g., samples per second), included in a report. The recommend VPRC may be provided in various ways, including pre-populating certain fields, and/or the like. A user interacts with the user interface display 500, reviews and/or modifies field accordingly, and submits an approved or modified VPRC. The VPRC is subsequently loaded onto an onboard system 50 as described herein, so that values of the indicated vehicle parameters are reported and/or logged based on the indicated reporting criterion (e.g., frequency, etc.).

### EXAMPLE DATA FLOW OF THE DISCLOSURE

Having described example systems, components thereof, and apparatuses in accordance with the present disclosure, an example data flow in accordance with the present disclosure will now be discussed. The example data flow may define particular data objects and/or data structures maintained by the example systems, devices, and/or apparatus described herein. Additionally or alternatively, in some embodiments, the data flows as depicted and described are performed via the systems, devices, and/or apparatuses as described above.

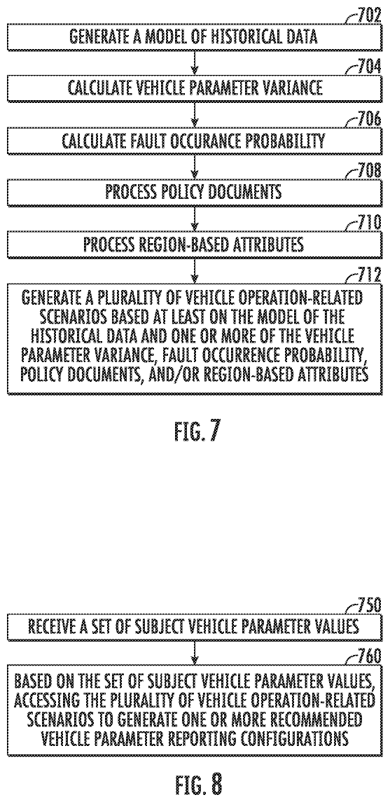

FIG. 6 illustrates that historical data 600 is processed by processor 102 to generate fault occurrence probability 610 and parameter variance 612. Vehicle parameter variance includes calculated prediction of variance, based on the model, of a value of a vehicle parameter, given a certain combination or set of other values of vehicle parameters. Vehicle parameter variance may be calculated as a percentage, for example. Fault occurrence probability 610 includes a calculated probability of a certain fault occurring given a certain combination of values of vehicle parameters. Fault occurrence probability may be calculated as a percentage, for example. See also at least FIG. 4, and the corresponding description including the processing of historical data 202 to perform the variance calculation 210 and fault occurrence probability calculation 212.

As illustrated in FIG. 6, policy documents 620 and/or region-based attributes 622 may be considered along with fault occurrence probability 610 and/or operational parameter variance 612 to generate vehicle operation-related scenarios 630. Policy documents 620 may include entity-specific policy documents and may be in any format including natural language and/or a structured data format. Policy documents may include requirements indicating how frequently or in what conditions certain vehicle parameters should be reported. Various parsing algorithms may be used to incorporate policy into the scenario generation as described in further detail below. In this regard, policy may override or may be weighted more heavily than variance calculations and/or fault occurrence probability. Different entities, or airlines, may have their own entity policy documents such that respective scenarios vary across entities and/or airline accordingly.

Region-based attributes 622 may include certain reporting criteria required by law, and/or certain region-attributes indicate that some vehicle parameters be identified as being more useful than others such that generated scenarios vary per region and/or per flight location, including departure location, arrival location, any region the vehicle or aircraft travels through, navigation related attributes, demographic related attributes (e.g., demographic limit), environment related attributes, condition related attributes, and/or any combination thereof.

The vehicle operation-related scenarios 630 generated with respect to FIG. 6 include computer-readable data comprising a set of one or more vehicle parameters and respective values and/or value ranges, along with associations with any number of corresponding recommended VPRCs that are recommended when subject vehicle parameters have one or more corresponding values that match or fall within one or more of the value ranges. The vehicle operation-related scenarios may be generated by the VPRC generation system based on vehicle parameter variance, fault occurrence probability, policy, region-based attributes, and/or the like.

As shown in FIG. 6, subject vehicle parameters, 640, such as values of vehicle parameters for a particular vehicle for which VPRC are requested and/or desired, are applied to the vehicle operation-related scenarios 630. Recommended VPRC 650 are generated accordingly based on matching subject vehicle parameters to values and/or value ranges from the vehicle-operational related scenarios.

Insights 652 may be optionally generated, and may include any rationale or explanation, such as to be provided to a user (e.g., engineer) as to why certain VPRCs are recommended. For example, an insight may include a description that a certain grouping of measurements are needed for maintenance purposes after 10,000 flight cycles, a certain number of miles traveled, and/or the like. The flow and transformation of data such as illustrated with respect to FIG. 6, provides improvements to the VPRC development system 30, by generating the recommended VPRCs.

### EXAMPLE PROCESSES OF THE DISCLOSURE

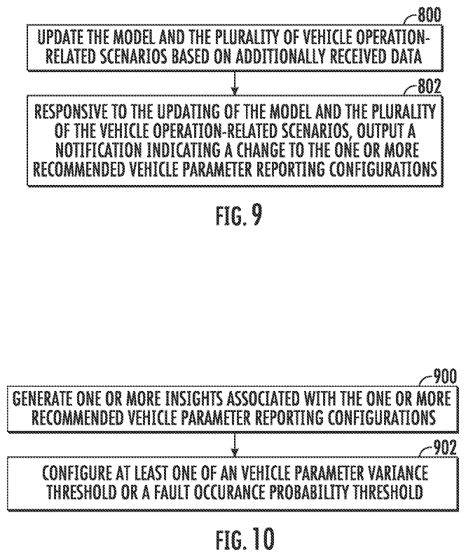

FIGS. 7-10 illustrate flowcharts including operations of an example computer-implemented process in accordance with at least one example embodiment of the present disclosure. It will be appreciated that each of the flowcharts depicts an example computer-implemented process that is performable by one or more of the apparatuses, systems, devices, and/or computer program products described herein, for example utilizing one or more of the specially configured components thereof.

The blocks indicate operations of each process. Such operations may be performed in any of a number of ways, including, without limitation, in the order and manner as depicted and described herein. In some embodiments, one or more blocks of any of the processes described herein occur in-between one or more blocks of another process, before one or more blocks of another process, in parallel with one or more blocks of another process, and/or as a sub-process of a second process. Additionally or alternatively, any of the processes in various embodiments include some or all operational steps described and/or depicted, including one or more optional blocks in some embodiments. With regard to the flowcharts illustrated herein, one or more of the depicted block(s) in some embodiments is/are optional in some, or all, embodiments of the disclosure. Similarly, it should be appreciated that one or more of the operations of each flowchart may be combinable, replaceable, and/or otherwise altered as described herein.

In some embodiments, the processes of FIGS. 7-10 are embodied by computer program code stored on a non-transitory computer-readable storage medium of a computer program product configured for execution to perform the processed as depicted and described. Alternatively or additionally, in some embodiments, the processes are performed by one or more specially configured computing devices, such as the apparatus 100 alone or in communication with one or more other component(s), device(s), system(s), and/or the like. In this regard, in some such embodiments, the apparatus 100 is specially configured by computer-coded instructions (e.g., computer program instructions) stored thereon, for example in the memory 104 and/or another component depicted and/or described herein and/or otherwise accessible to the apparatus 100, for performing the operations as depicted and described. In some embodiments, the apparatus 100 is in communication with one or more external apparatus(es), system(s), device(s), and/or the like, to perform one or more of the operations as depicted and described. For example, the apparatus 100 in some embodiments is in communication with at least one apparatus, at least one physical component, at least one audio output, intermediary device, and/or the like. For purposes of simplifying the description, the processes are described as performed by and from the perspective of the apparatus 100.

Although the example processes depict particular sequences of operations, the sequence may be altered without departing from the scope of the present disclosure. For example, some of the operations depicted may be performed in parallel or in a different sequence that does not materially affect the function thereof. In other examples, different components of an example device or system that implements the processes may perform functions at substantially the same time or in a specific sequence.

The flowchart of FIG. 7 provides an example process for generating vehicle operation-related scenarios. As shown by operation 702, apparatus 100, such as the VPRC generation system 22, includes means, such as processor 102, memory 104, communications circuitry 108, and/or the like, for generating a model of historical data. See for example, historical data 202 of FIG. 4. The modeled historical data may include any vehicle parameter values previously recorded, and corresponding outcomes, such as but not limited to fault occurrences. Processor 102 accesses numerous historical data, such as, but not limited to various parameter recordings, continuous parameter logging data, reports, fault history, uplink messages, downlink message and/or the like, and stores data on memory 104. The historical data may be received in various formats and over time as flight leg data is collected, for example. The processor 102 may structure the data on memory 104 in a format that can be efficiently processed subsequently to generate vehicle operation-related scenarios accordingly.

To generate the model, processor 102 iterates through and combines different vehicle parameter values from the historical data, such as values for each vehicle parameter, each member system, and/or subsystem. Different combinations of the vehicle parameters, including sets of vehicle parameters within a subsystem and/or across subsystems may be contemplated and generated as different sets of vehicle parameter values inserted in the model. According to certain embodiments, the processor 102 may iterate every combination of vehicle parameters and potential values and/or ranges that could feasibly occur.

It will be appreciated that according to certain embodiments, not every combination of vehicle parameters is recorded in historical data. In this regard, according to certain embodiments, one or more machine learning algorithms may be applied to the model and/or historical data to insert predicted values of vehicle parameters based on values of other vehicle parameters. In this regard, machine learning algorithms, including deep learning algorithms, may process the vehicle parameters values from the model, such as to expand upon the model. The processor 102 may predict values of certain vehicle parameters based on patterns identified in the various combinations or sets of vehicle parameter values and populate predictive values of other vehicle parameters based on certain combinations accordingly. In this regard, the VPRC generation system 22 may incorporate into the model, predictive values and/or ranges of vehicle parameter values based on historical data. Additional sets of vehicle parameters values may therefore be included in the model that include ones or more predicted values and/or ranges thereof.

The VPRC generation system 22 may utilize the model to calculate vehicle parameter variance and/or fault occurrence probability, which are further utilized to generate vehicle operation-related scenarios as described below. As shown by operation 704, apparatus 100, such as the VPRC generation system 22, includes means, such as processor 102, memory 104, communications circuitry 108, and/or the like, for calculating vehicle parameter variance. See for example, calculation 210 of FIG. 4. The variance may be calculated as an average of the variance for all values of the vehicle parameters for a subsystem or defined grouping of vehicle parameters, given a certain set of other vehicle parameters. According to certain embodiments, the vehicle parameter variance of one set of parameter values may be a predicted vehicle parameter variance based on predictions of other vehicle parameter values. In this regard, according to certain embodiments, machine learning algorithms may be applied to the model to predict variance calculations for data sets that may not necessarily be represented in the model and/or historical data. In this regard, machine learning algorithms, including deep learning algorithms, may determine various weights of, or impacts of certain vehicle parameters in impacting variance.

As shown by operation 706, apparatus 100, such as the VPRC generation system 22, includes means, such as processor 102, memory 104, communications circuitry 108, and/or the like, for calculating fault occurrence probability. See for example calculation 212 of FIG. 4. The fault occurrence probability includes a calculated probability of a certain fault occurring given a certain combination of values of vehicle parameters. According to certain embodiments, the fault occurrent probability of one set of parameter values may be a predicted fault occurrence probability based on predictions of other vehicle parameter values. In this regard, according to certain embodiments, machine learning algorithms may be applied to the model to predict fault occurrence probability for data sets that may not necessarily be represented in the model and/or historical data. In this regard, machine learning algorithms, including deep learning algorithms, may determine various weights of, or impacts of certain vehicle parameters in impacting fault occurrence probability.

As shown by operation 708, apparatus 100, such as the VPRC generation system 22, includes means, such as processor 102, memory 104, communications circuitry 108, and/or the like, for processing policy documents. See for example entity policy documents 220 and regulation policy documents 222, and policy processing 224 of FIG. 4. Policy documents may include entity-specific policy documents and may be in any format including natural language and/or a structured data format. Policy documents may include requirements indicating how frequently or in what conditions certain vehicle parameters should be reported. Various parsing algorithms may be used to incorporate policy into the scenario generation as described in further detail below. In this regard, policy may override or may be weighted more heavily than variance calculations and/or fault occurrence probability.

As shown by operation 710, apparatus 100, such as the VPRC generation system 22, includes means, such as processor 102, memory 104, communications circuitry 108, and/or the like, for processing region-based attributes. See for example, 234 of FIG. 4. Region-based information may include requirements indicating how frequently or in what conditions certain vehicle parameters should be reported when a vehicle travels in certain regions or locations (which may include a including departure location, arrival location, any region the vehicle or aircraft travels through, and/or any combination thereof). Various parsing algorithms may be used to incorporate region-based attributes into the scenario generation as described in further detail below. In this regard, region-based may override or may be weighted more heavily than variance calculations and/or fault occurrence probability.

As shown by operation 712, apparatus 100, such as the VPRC generation system 22, includes means, such as processor 102, memory 104, communications circuitry 108, and/or the like, for generating a plurality of vehicle operation-related scenarios based at least on the model of the historical data and optionally one or more of the vehicle parameter variance, fault occurrence probability, policy documents, and/or region-based attributes. In this regard, apparatus 100, such as the VPRC generation system 22, includes means, such as processor 102, memory 104, communications circuitry 108, and/or the like, for utilizing the model, and by calculating at least one of vehicle parameter variance and/or fault occurrence probability (and optionally policy documents and/or region-based attributes) to generate a plurality of vehicle operation-relation scenarios.

For each set of vehicle parameters values (including from historical data, and predicted values), inserted into the model, the VPRC generation system 22 determines sets of vehicle parameters values for which a calculated variance and/or fault occurrence probability exceeds or meets a respective predetermined threshold. For those data sets having a calculated variance and/or fault occurrence probability that exceeds or meets the respective predetermined threshold, the combination of vehicle parameters, and respective values and/or value ranges are stored as vehicle operation-related scenarios in the scenario database 242. Additionally or alternatively, policy and/or region-based attributes may be considered alongside variance and/or fault occurrent probability to determine scenario generation.

Policy and/or region-based attributes may be weighted differently than and/or may override variance calculations and/or fault occurrence probability. Policy data or documents may relate to any policies specific to entities (e.g., airlines), local jurisdictions, and/or the like, and may therefore vary across entities, jurisdiction, and/or the like. Additionally or alternatively, certain vehicle parameters may be weighted differently than others. As an example, if a policy indicates a more frequent reporting of certain vehicle parameters than what is generated based on variance calculation, the policy may override such scenarios to satisfy policy requirements, such that certain vehicle parameters set are reported more frequently than if only variance and/or fault occurrence probability was considered in the scenario generation without policy and/or region-based attributes. Additionally or alternatively, if a region-based attributes indicate a more frequent reporting of certain vehicle parameters than what is generated based on variance calculation and/or the probability of fault occurrence, the region-based attributes may override such scenarios to satisfy policy requirements, such that certain vehicle parameters set are reported more frequently than if only variance and/or fault occurrence probability was considered in the scenario generation without policy and/or region-based attributes. As another example, region-based attributes may impact what vehicle parameters are incorporated into the scenario generation. For example, in certain regions, certain reporting criteria may be required by law, and/or certain region-attributes may result in some vehicle parameters be identified as being more useful than others such that generated scenarios vary per region and/or per flight location, including departure location, arrival location, any region the vehicle or aircraft travels through, and/or any combination thereof. Any variation of weighting and/or overriding of inputs to the scenario generation may be contemplated. Accordingly, the scenario database 242 of vehicle operation-related scenarios is built upon and maintained to contain a large amount of varying vehicle parameter values, ranges, and/or the like along with corresponding recommended vehicle parameters for the respective values and/or ranges. According to certain embodiments, the scenario database 242 may include initialized of default values of certain vehicle parameters.

FIG. 8 illustrates an example process for generating recommended VPRCs according to example embodiments. As shown by operation 750, apparatus 100, such as the VPRC generation system 22, includes means, such as processor 102, memory 104, communications circuitry 108, and/or the like, for receiving a set of subject vehicle parameter values. The set of subject vehicle parameters values may relate to a vehicle, such as an aircraft, for which an engineer or other user wants to review and/or modify the VPRC. A user may access the VPRC development system to initiate review and/or modification of the VPRC. The set of subject vehicle parameter values may include any data pertaining to the vehicle for which the VPRC is requested.

As shown by operation 760, apparatus 100, such as the VPRC generation system 22, includes means, such as processor 102, memory 104, communications circuitry 108, and/or the like, for based on the set of subject vehicle parameter values, accessing the plurality of vehicle operation-related scenarios to generate one or more recommended vehicle parameter reporting configurations. The processor 102 queries or accesses the scenario database 242 using the subject vehicle parameter values and generates the VPRC based on returned or identified vehicle operation-related scenarios. The recommended VPRCs may be populated in the VPRC development system 20, for example, and approved and/or modified by an engineer or other user, such as with user device 10.

As shown by operation 770, apparatus 100, such as the VPRC generation system 22 and/or VPRC development system 20, includes means, such as processor 102, memory 104, input/output circuitry 106, communications circuitry 108, and/or the like, for providing an indication of the one or more recommended vehicle parameter reporting configurations via a vehicle parameter reporting configuration development system. In this regard, descriptions of recommended vehicle parameter reporting configurations are displayed, provided and/or defaulted for viewing in a user interface.

As shown by operation 780, apparatus 100, such as the VPRC generation system 22, and/or VPRC development system 20 includes means, such as processor 102, memory 104, input/output circuitry 106. communications circuitry 108, and/or the like, for, via the vehicle parameter reporting configuration development system 20, receiving an indication of at least one of a selection, a modification, or a submission of the one or more recommended vehicle parameter reporting configurations. In this regard, a user or engineer reviews, selects, modifies and/or submits data representing the one or more recommended vehicle parameter reporting configurations.

As shown by operation 790, apparatus 100, such as the VPRC generation system 22, and/or VPRC development system 20 includes means, such as processor 102, memory 104, communications circuitry 108, and/or the like, for, transmitting the one or more recommended vehicle parameter reporting configurations (which may be optionally modified according to user input) to an onboard system. Approved and/or submitted VPRCs may then be loaded onto an onboard system 50 to direct the onboard system 50 and/or subsystems thereof to record data according to the VPRC, such as during operation of the vehicle. The onboard system 50 directs reporting of vehicle parameter values based on the one or more recommended vehicle parameter reporting configurations.

FIG. 9 illustrates an example process for continually updating the model and/or scenario database over time and/or as new data is received and/or recorded from various onboard systems 50. In operation 800, apparatus 100, such as the VPRC generation system 22, includes means, such as processor 102, memory 104, communications circuitry 108, and/or the like, for updating the model and the plurality of vehicle operation-related scenarios based on additionally received data. As flight operations occur, various data is recorded onto memory 104, such as according to configured VPRCs. A GBST and/or other applications may access such data to enable or facilitate troubleshooting, maintenance tasks, operational improvements and/or the like. The additionally received data may be further fed into the processes and operations described herein utilized to generate vehicle operation-related scenarios and corresponding recommended VPRCs, to continually update and improve related systems. In this regard, any of the operations described herein may be repeatedly performed using additionally received data. For example, the operations 204, 206, 208, 210, and/or 212 may be iteratively or continually performed. Entity policy documents 220, regulation policy documents 222 and/or region information 232 may be updated. Accordingly, any newly received data may impact the scenario database 242 such that new scenarios and/or updated scenarios are provided.

As shown by operation 802, apparatus 100, such as the VPRC generation system 22, includes means, such as processor 102, memory 104, input/output circuitry 106, communications circuitry 108, and/or the like, for, responsive to the updating of the model and the plurality of the vehicle operation-related scenarios, outputting a notification indicating a change to the one or more recommended vehicle parameter reporting configurations. In this regard, a user or engineer may be notified of recommended changes based on updated or new scenario(s). For example, a change in a regulation could result in an update to an existing vehicle operation-related scenario, or new vehicle operation-related scenario(s). A notification may be provided when a user accesses and/or log ins to the VPRC development system 20, for example, and/or by email or other electronic communication methods. Transmitting the notification to a user or engineer provides an improvement to the VPRC development system 20. Particularly when there are many vehicle parameters, travel itineraries and/or flights plans, such as in the commercial airline industry, a user or other engineer may be quickly or efficiently notified of recommended changes. Without the advantages of the disclosed embodiments, a user may other not arrive at the recommended VPRCs, but additionally or alternatively, such changes may be delayed and/or applied with a much slower reaction to changes in vehicle parameters, fault occurrent, policy, and/or region attributes. Accordingly, without advantages of the claimed embodiments, troubleshooting, optimal fault prediction, and/or operational optimization may be hindered. Example embodiments improve upon existing systems by proactively alerting engineers of recommended VPRCs, and recommended changes detected over time.

FIG. 10 shows an example process that may be performed according to example embodiments. As shown by operation 900, apparatus 100, such as the VPRC generation system 22, includes means, such as processor 102, memory 104, communications circuitry 108, and/or the like, for generating one or more insights associated with the one or more recommended vehicle parameter reporting configurations. An insight may include any rationale or explanation, such as to be provided to a user (e.g., engineer) as to why certain VPRCs are recommended, and may help a user or engineer understand the reason for the recommendation, to assist in approving or further modifying the VPRC.

As shown in operation 902, apparatus 100, such as the VPRC generation system 22, includes means, such as processor 102, memory 104, input/output circuitry 106, communications circuitry 108, and/or the like, for configuring at least one of a vehicle parameter variance threshold or a fault occurrence probability threshold. A user may use a user device 10 to set or modify thresholds, such as those utilized in operations 214 and 216 of FIG. 4. The thresholds may be used to indicate that when certain vehicle parameters result in variance or fault occurrent probability meeting or exceeding the specified amount, that certain vehicle operation-related scenarios are generated and result in recommended VPRC accordingly. Different variance thresholds and/or fault occurrence probability thresholds may be configured for different groupings of vehicle parameters, vehicle parameters reported by different subsystems, and/or the like. Different entities, such as airlines, may configure certain thresholds differently for their own needs.

Example embodiments provided herein may therefore improve upon existing systems, such as the VPRC development system 20 and/or the system of FIG. 1, by incorporating a VPRC generation system 22. According to certain embodiments, troubleshooting mechanisms and maintenance-related systems of a vehicle, such as an aircraft, may be improved, as well as the overall performance of the onboard system 50 and its subsystems, by enhancing an AMI capability to record recommended data. The data recorded as a result of the recommended VPRCs can be used for troubleshooting failures, optimizing aircraft operations by technicians, and/or the like. Example embodiments additionally provide a guidance mechanism for identifying changes in regulation and entity (e.g., airline) policies and to incorporate such changes into the vehicle operation-related scenarios. The vehicle operation-related scenarios may be further impacted by region-based attributes, such that the recommended VPRCs incorporate the region information. The VPRC, such as AMI, is therefore enhanced to improve troubleshooting processes, maintenance routines, airline operations, and/or the like. Implementing such embodiments with computer-based and network-based technology leverages large amounts of data, and with highly efficient response to changes in operating conditions, policy, and/or the like, that could not otherwise be practically replicated by engineers only using an existing VPRC development system, pen and paper methods, and/or the like.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more modules of computer program instructions, encoded on computer storage medium for execution by, or to control the operation of, information/data processing apparatus. Alternatively, or in addition, the program instructions can be encoded on an artificially generated propagated signal, e.g., a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or be included in, one or more separate physical components or media (e.g., multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a repository management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or information/data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto-optical disks, or optical disks. However, a computer need not have such devices. Devices suitable for storing computer program instructions and information/data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a CRT (cathode ray tube) or LCD (liquid crystal display) monitor, for displaying information/data to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, e.g., as an information/data server, or that includes a middleware component, e.g., an application server, or that includes a front-end component, e.g., a client computer having a graphical user interface or a web browser through which a user can interact with an implementation of the subject matter described herein, or any combination of one or more such back-end, middleware, or front-end components. The components of the system can be interconnected by any form or medium of digital information/data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) can be received from the client device at the server.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

1. A computer-implemented method comprising:
generating a plurality of vehicle operation-related scenarios utilizing a model of historical data by at least calculating at least one of vehicle parameter variance or fault occurrence probability based at least in part on the model;
receiving a set of subject vehicle parameter values; and
based at least in part on the set of subject vehicle parameter values, accessing the plurality of vehicle operation-related scenarios to generate one or more recommended vehicle parameter reporting configurations, wherein the one or more recommended vehicle parameter reporting configurations comprise at least one vehicle parameter and an associated reporting criterion.

2. The computer-implemented method of claim 1, further comprising:
processing policy documents and region-based attributes to generate the plurality of vehicle operation-related scenarios.

3. The computer-implemented method of claim 1, wherein the one or more vehicle parameter reporting configurations comprise airline modifiable information.

4. The computer-implemented method of claim 1, further comprising:
updating the model and the plurality of vehicle operation-related scenarios based at least in part on additionally received data; and
responsive to the updating of the model and the plurality of the vehicle operation-related scenarios, outputting a notification indicating a change to the one or more recommended vehicle parameter reporting configurations.

5. The computer-implemented method of claim 1, wherein the associated reporting criterion comprises at least one of a frequency of reporting, a retention period, or a retention policy.

6. The computer-implemented method of claim 1, wherein the historical data comprises one or more of reports, fault history, or vehicle messaging information.

7. The computer-implemented method of claim 1, further comprising generating one or more insights associated with the one or more recommended vehicle parameter reporting configurations.

8. The computer-implemented method of claim 1, further comprising configuring at least one of an operational parameter variance threshold or a fault occurrence probability threshold.

9. The computer-implemented method of claim 1, further comprising:
generating the model by:
combining different vehicle parameter values from the historical data to insert as sets of vehicle parameters values in the model; and
applying one or more machine learning algorithms to insert predicted vehicle parameter values in the model.

10. The computer-implemented method of claim 1, further comprising:
providing the one or more recommended vehicle parameter reporting configurations via a vehicle parameter reporting configuration development system;
receiving an indication of at least one of a selection, a modification, or a submission of the one or more recommended vehicle parameter reporting configurations; and
transmitting the one or more recommended vehicle parameter reporting configurations to an onboard system, wherein the onboard system directs reporting of vehicle parameter values based on the one or more recommended vehicle parameter reporting configurations.

11. An apparatus comprising at least one processor and at least one memory, the at least one memory having computer-coded instructions stored thereon that, when executed by the least one processor, cause the apparatus to:
generate a plurality of vehicle operation-related scenarios utilizing a model of historical data by at least calculating at least one of vehicle parameter variance or fault occurrence probability based at least in part on the model;
receive a set of subject vehicle parameter values; and
based at least in part on the set of subject vehicle parameter values, access the plurality of vehicle operation-related scenarios to generate one or more recommended vehicle parameter reporting configurations, wherein the one or more recommended vehicle parameter reporting configurations comprise at least one vehicle parameter and an associated reporting criterion.

12. The apparatus of claim 11, wherein the computer-coded instructions, when executed by the least one processor, further cause the apparatus to:
process policy documents and region-based attributes to generate the plurality of vehicle operation-related scenarios.

13. The apparatus of claim 11, wherein the one or more vehicle parameter reporting configurations comprise airline modifiable information.

14. The apparatus of claim 11, wherein the computer-coded instructions, when executed by the least one processor, further cause the apparatus to:
update the model and the plurality of vehicle operation-related scenarios based at least in part on additionally received data; and
responsive to the updating of the model and the plurality of the vehicle operation-related scenarios, output a notification indicating a change to the one or more recommended vehicle parameter reporting configurations.

15. The apparatus of claim 11, wherein the associated reporting criterion comprises at least one of a frequency of reporting, a retention period, or a retention policy.

16. The apparatus of claim 11, wherein the historical data comprises one or more of reports, fault history, or vehicle messaging information.

17. The apparatus of claim 11, wherein the computer-coded instructions, when executed by the least one processor, further cause the apparatus to:
generate one or more insights associated with the one or more recommended vehicle parameter reporting configurations.

18. The apparatus of claim 11, wherein the computer-coded instructions, when executed by the least one processor, further cause the apparatus to:
configure at least one of an operational parameter variance threshold or a fault occurrence probability threshold.

19. The apparatus of claim 11, wherein the computer-coded instructions, when executed by the least one processor, further cause the apparatus to:
generate the model by:
combining different vehicle parameter values from the historical data to insert as sets of vehicle parameters values in the model; and
applying one or more machine learning algorithms to insert predicted vehicle parameter values in the model.

20. The apparatus of claim 11, wherein the computer-coded instructions, when executed by the least one processor, further cause the apparatus to:
provide an indication of the one or more recommended vehicle parameter reporting configurations via a vehicle parameter reporting configuration development system;
receive an indication of at least one of a selection, a modification, or a submission of the one or more recommended vehicle parameter reporting configurations; and
transmit the one or more recommended vehicle parameter reporting configurations to an onboard system, wherein the onboard system directs reporting of vehicle parameter values based on the one or more recommended vehicle parameter reporting configurations.

21. A system comprising:
a vehicle parameter reporting configuration generation system configured to:
generate a plurality of vehicle operation-related scenarios;
generate one or more recommended vehicle parameter reporting configurations, wherein the one or more recommended vehicle parameter reporting configurations comprise at least one vehicle parameter and an associated reporting criterion; and
provide an indication of the one or more recommended vehicle parameter reporting configurations to a vehicle parameter reporting configuration development system;
and
the vehicle parameter reporting configuration development system, configured to:
facilitate review, modification and submission of the recommended vehicle parameter reporting configurations to an onboard system, wherein the onboard system directs reporting of vehicle parameter values based on the one or more recommended vehicle parameter reporting configurations.
